(19) United States
(12) Patent Application Publication
(10) Pub. No.: US 2019/0062908 A1
(43) Pub. Date: Feb. 28, 2019

(54) SEMICONDUCTOR PROCESS KIT WITH NANO STRUCTURES

(71) Applicants: SURANJAN DABARE, COLOMBO (LK); RAVI THIRUN, MARKHAM (CA); UMASHANKAR PARAMSOTHY, COLOMBO (LK); ROMMEL MONTES, CALGARY (CA)

(72) Inventors: SURANJAN DABARE, COLOMBO (LK); RAVI THIRUN, MARKHAM (CA); UMASHANKAR PARAMSOTHY, COLOMBO (LK); ROMMEL MONTES, CALGARY (CA)

(21) Appl. No.: 15/683,154

(22) Filed: Aug. 22, 2017

(51) Int. Cl. C23C 16/458; H01L 21/687; C23C 16/455; C23C 16/44

(52) U.S. Cl. CPC C23C 16/4585; H01L 21/68721; C23C 16/4412; C23C 16/4402; C23C 16/45523

(57) ABSTRACT

A chemical deposition process kit component comprises a surface exposed to a deposited thin film when the component is in use in a process chamber. The surface comprises a plurality of recesses that are substantially half spherical in shape. The density of the plurality of recesses is proportional to the amount of the deposited thin film that accumulates on the component when in use. The plurality of recesses may be formed using a mechanical drilling process or a laser removal process.

### FIELD OF THE INVENTION

The present invention relates to semiconductor manufacturing equipment and more particularly to process kits used in CVD and PVD processing equipment.

### BACKGROUND OF THE INVENTION

Semiconductor manufacturing processes involve techniques such as PVD (Physical Vapor Deposition) and CVD (Chemical Vapor Deposition) techniques to deposit very thin layers of materials onto semiconductor substrates. In PVD, a pure source material is gasified via evaporation and allowed to condense on the substrate material to create the desired layer. In CVD, the source material is mixed with a volatile carrier. The mixture is injected into a reaction chamber that contains the substrate and deposited onto the substrate. The byproduct is then removed from the chamber via gas flow.

Process kits are replaceable parts using in PVD and CVD process chambers that have a fixed life span before process defects rise and they must be replaced. CVD kits include components such as chamber inserts, inner shields, outer shields, and edge rings. PVD kits include inner shields, cover rings, deposition rings, and shutter disks.

As process kits reach the end of their life a number of undesirable effects start to occur that include increased number manufacturing defects, arcing, contamination of chambers, and a need for more frequent maintenance.

Current solutions in the industry include adding coatings to the kit parts that help to increase yield. This helps relieve some issues but is an expensive solution that often leads to reducing the lifespan of the kit components and can only be used on metal components, not ceramic ones.

There exists a need for PVD and CVD process kits with extended life span that alleviates the drawbacks of the present kit components to increase yield and lower costs.

Other aspects and features of the present invention will become apparent to those ordinarily skilled in the art upon review of the following description of specific embodiments of the invention in conjunction with the accompanying figures.

### BRIEF SUMMARY OF THE INVENTION

It is an object of the present invention to mitigate limitations within the prior art relating to the longevity of chemical deposition process kits and more particularly to reducing the amount of thin film flaking and resulting defects when used in a semiconductor manufacturing process.

Embodiments of the invention include a chemical deposition process kit component comprising a surface exposed to a deposited thin film when the component is in use in a process chamber. The surface comprises a plurality of recesses and the plurality of recesses being substantially half spherical in shape.

In further embodiments, the density of the plurality of recesses is proportional to the amount of the deposited thin film that accumulates on the component when in use.

Other embodiments include a chemical deposition process kit comprising a component comprising a surface exposed to a deposited thin film when the component is in use in a process chamber. The surface comprising a plurality of recesses and the plurality of recesses being substantially half spherical in shape.

Other embodiments include a process for modifying a chemical deposition process kit component comprising determining a portion of surface of the component that is exposed to a deposited thin film when the component is in use in a process chamber. Determining an amount of the deposited thin film accumulated on the portion of surface. Forming a plurality of recesses in within the portion of surface where the density of the plurality of recesses is proportional to the amount of the deposited thin film accumulated on the portion of surface.

In further embodiments, the plurality of recesses are substantially half spherical in shape.

In further embodiments, the plurality of recesses are formed using a mechanical drilling process or the plurality of recesses are formed using a laser removal process.

Other aspects and features of the present invention will become apparent to those ordinarily skilled in the art upon review of the following description of specific embodiments of the invention in conjunction with the accompanying figures.

### BRIEF DESCRIPTION OF THE DRAWINGS

Embodiments of the present invention will now be described, by way of example only, with reference to the attached Figures, wherein:

FIG. 1 depicts components used in a CVD process kit;

FIG. 2 depicts components used in a PVD process kit;

FIG. 3 depicts a planar view of a surface with nano-structures;

FIG. 4 depicts a perspective view of a surface with nano-structures;

FIG. 5 depicts a planar view of one layout of nano-structures;

FIG. 6 depicts a planar view of another layout of nano-structures;

FIG. 7 depicts a planar view of a third layout of nano-structures;

FIG. 8 depicts a planar view of a layout of nano-structures illustrating methods of measuring the distances between them.

### DETAILED DESCRIPTION

The present invention is direct to improving the longevity and performance of PVD and CVD process kits and more particularly to the addition of numerous nano-structures to the kit components.

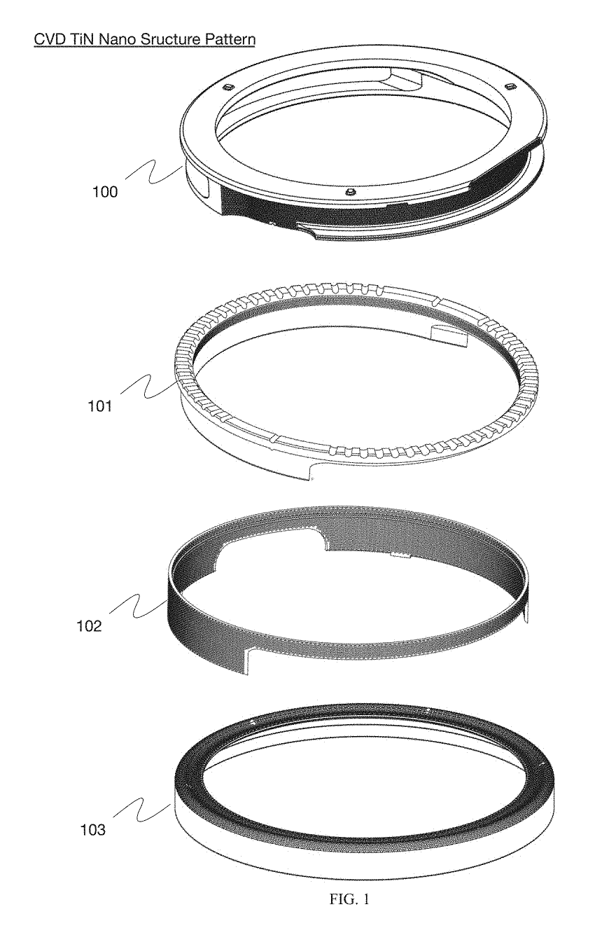

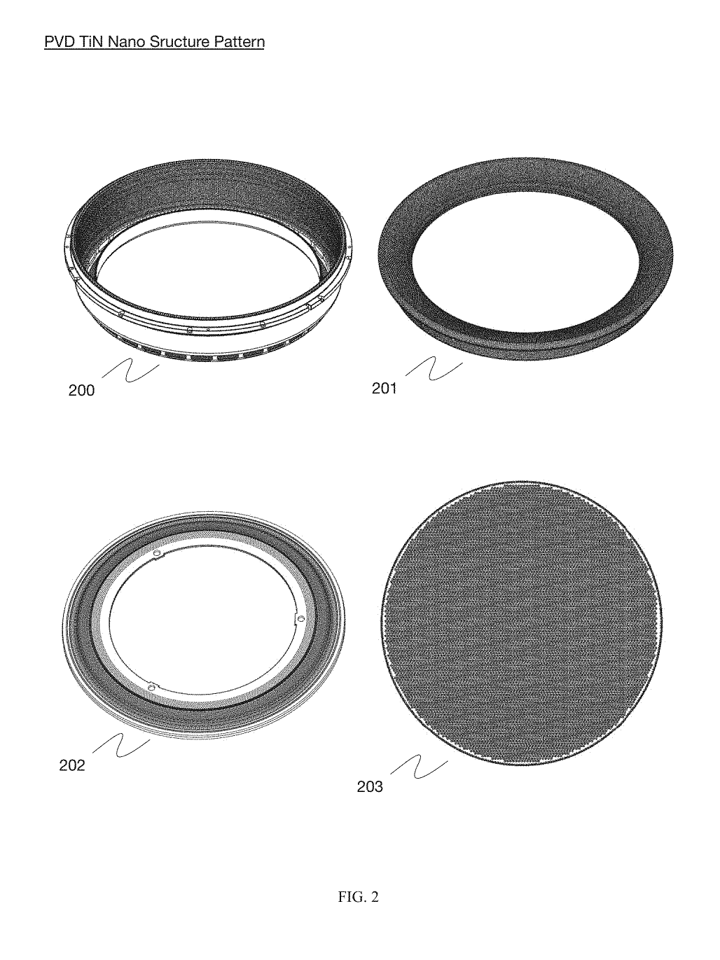

Referring to FIGS. 1 and 2, embodiments of the invention comprise structures, specifically nano-structures that are permanently applied on the process kit part's identified surface. In FIGS. 1 and 2, the nano-structures can be seen as the shaded portions of the kit parts displayed. FIG. 1 shows the placement of nano-structures on commonly used CVD kit parts such as chamber inserts 100, inner shields, 101, outer shields 102, and edge rings 103. FIG. 2 shows the placement of nano-structures on commonly used PVD kit parts such as inner shields 200, cover rings, 201, deposition rings 202, and shutter disks 203. It should be noted that nano-structures according to embodiments of the invention may also be applied to other parts and surfaces, not illustrated, that suffer from stress and flaking of deposited films.

The pattern and density of the nano-structures may be uniform over a small area but are often non-uniform over the entire surface of the kit part. Distribution of the nano-structure varies on the surface area of the process kit part. The placement and pattern of the nano-structures help to counter balance and distribute the film stress that occurs during their use in PVD and CVD processes. The density, pattern, shape, and dimensions of the nano-structures can vary over the surfaces of process kit parts having a higher or lower density of nano-structures depending on the amount of stress experienced by thin film depositions when in use. In general, the higher the amount of stress, the more nano-structures should be used. By varying the amount and density of nano-structures the stress may be uniformly distributed over the process kit part.

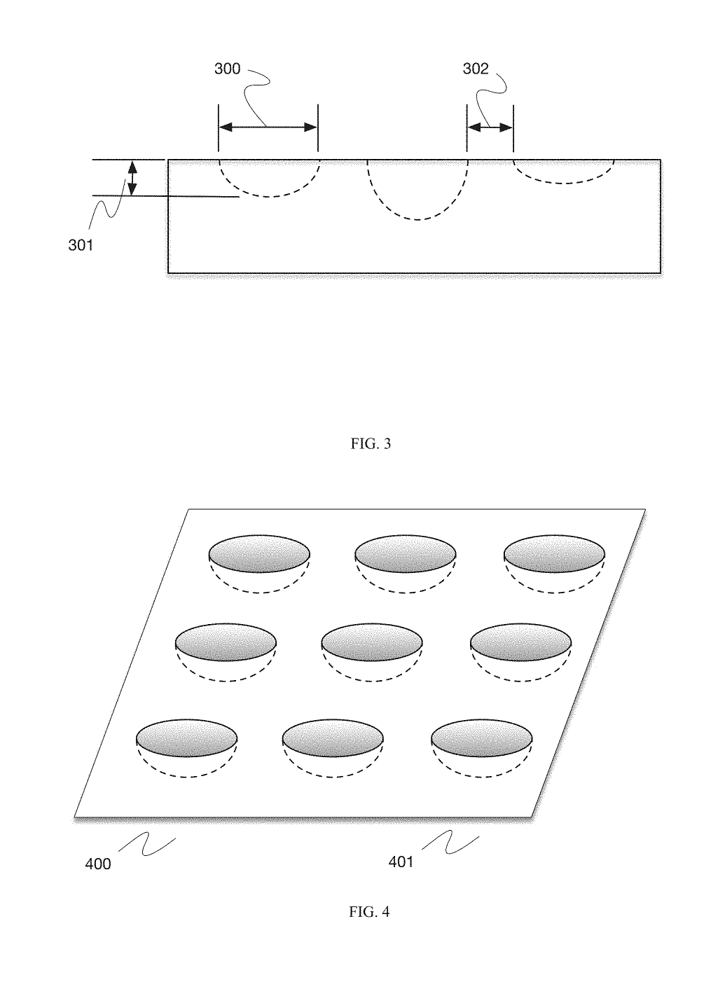

Referring to FIG. 3, nano-structures may be added to kit parts in a manner that the physical size of the kit parts remain the same and the kit parts modified with nano-structures can be used in the place of unmodified kit parts without further modifications. The quantity of the nano-structure may vary depending on the size of the kit as for larger kit parts there is more area to may fit more nano-structures. By calculating the relevant surface area and setting the design distances it is possible to calculate the number of nano-structure that may be placed. In preferred embodiments, the minimum distance between nano-structures is determined by manufacturing tolerances and techniques. In preferred embodiments, each nano-structure has an approximately half-spherical or semi-spherical shape and is formed into the surface of the kit part. In cases where the depth 301 of the nano-structure is less than half the diameter 300, the shape will be semi-spherical. In cases where the depth 301 of the nano-structure is approximately the same as the radius of the structure the shape will be half-spherical. In most embodiments, the bottom of the nano-structure will have a round shape. Referring to FIG. 3, in an exemplary embodiment, each nano-structure is 2 mm in diameter 300 in the horizontal plane, 1 mm in depth 301, with 1 mm between 302 adjacent nano-structures. In another exemplary embodiment, each nano-structure is 3 mm in diameter 300 in the horizontal plane, 0.8 mm in depth 301. Nano-structures of different diameters, depth, and spacing may also be combined in the same process kit component. Other sizes and shapes may be determined experimentally for different applications.

PVD and CVD kit components may be made from a number of materials including aluminum, stainless steel and ceramic. The nano-structures themselves may be formed in a number of ways including mechanical drilling, or laser removal of material.

In other embodiments, the kit part with nano-structures may be further processed with sand blasting or by the application of an aluminum coating to further increase the surface roughness.

When in use, the PVD and CVD process kit components treated with nano-structures may replace similar OEM or third party components that do not have nano-structures. Embodiments of the invention are used until their kit life has been reached and then may be cleaned using techniques as known in the art of semiconductor manufacturing or replaced.

FIG. 4 illustrated different layouts and spacing that may be used in embodiments of the invention. The nano-structures may be placed as close as 1 mm apart but in an exemplary embodiment are placed 2.6 mm apart. In general, where particle deposition is high, more nano-structures should be added leading to a higher density of nano-structures. Optimal placements, patterns, and density of the nano-structures can be determined experimentally by examining there the flaking of deposited film starts, where arcing occurs, where plasma leaks, where heat distribution is uneven, and other manufacturing issues manifest themselves. Nano-structures should be placed where manufacturing issues are most likely to happen and where experimentation has shown them to improve the process.

FIG. 5 illustrates a nano-structure layout where the nano-structures in adjacent rows are aligned in both the x and y direction.

FIG. 6 illustrates a nano-structure layout where the nano-structures in adjacent rows may be offset from each other in either the x or y direction.

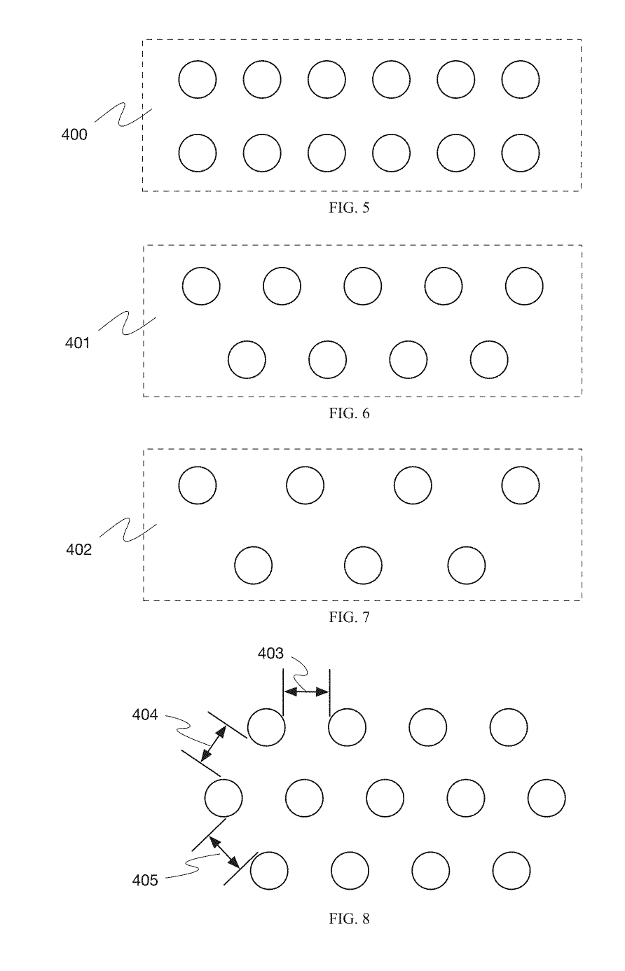

FIG. 7 illustrates a less dense nano-structure layout where the nano-structures in adjacent rows may be offset from each other in either the x or y direction.

FIG. 8 illustrates a nano-structure layout where the nano-structures in adjacent rows may be offset from each other in either the x or y direction. The distances 403, 404, and 405 between nano-structures are determined experimentally within the limits of manufacturing technology.

Referring again to the CVD process kit components of FIG. 1, chamber insert 100 may have nano-structures placed with surface patterns to optimized the surface roughness for better defects control. Inner Shield 101 may have nano-structures placed to optimize the surface pattern to minimize defects. Outer Shield 102 may have nano-structures added in surface patterns on both the inner and outer surface for better control of defects. Edge ring 103 may have nano-structures added to help with installation issues and a pattern may be used to prevent or minimize mechanical interference. Showerheads used in process kits may have a surface pattern implemented to minimize manufacturing defects including adding a CIP pattern at weaker surfaces to minimize defects and to maintain the flatness and the diameter of the holes. The top shield may have a nano-structure pattern on its bottom inner surface to prevent thin film materials from flaking-off and causing defects. A lid isolator may have nano-structures added in patterns to optimize the surface texture to minimize manufacturing defects.

Referring again to the PVD process kit components of FIG. 2, inner shield 200 may have nano-structures placed for an optimized profile to minimize or eliminate “target” level arcing and to minimize or eliminate plasma leak issues. Nano-structures may be placed on cover ring 201 to minimize or eliminate wafer level arcing and minimize or eliminate plasma leak issues. The nano-structures may also be placed to minimize or eliminate stress build up during annealing processes. Nano-structures may be placed on deposition ring 202 on surfaces to minimize or eliminate wafer level arcing, reduce or eliminate plasma leak, and optimized manufacturing process for flatness control and maintenance. Shutter disks 203 according to embodiments of the invention help to eliminate wafer level arcing and the nano-structures may be placed or the density of nano-structures can be increased where this is an area of concern. Nano-structures may also be placed to maintain flatness post heat or cool cycle during manufacturing. In general, nano-structures on the surface help to increased surface area for better defects control.

The ensuing description provides representative embodiment(s) only, and is not intended to limit the scope, applicability or configuration of the disclosure. Rather, the ensuing description of the embodiment(s) will provide those skilled in the art with an enabling description for implementing an embodiment or embodiments of the invention. It being understood that various changes can be made in the function and arrangement of elements without departing from the spirit and scope as set forth in the appended claims. Accordingly, an embodiment is an example or implementation of the inventions and not the sole implementation. Various appearances of “one embodiment,” “an embodiment” or “some embodiments” do not necessarily all refer to the same embodiments. Although various features of the invention may be described in the context of a single embodiment, the features may also be provided separately or in any suitable combination. Conversely, although the invention may be described herein in the context of separate embodiments for clarity, the invention can also be implemented in a single embodiment or any combination of embodiments.

Reference in the specification to “one embodiment”, “an embodiment”, “some embodiments” or “other embodiments” means that a particular feature, structure, or characteristic described in connection with the embodiments is included in at least one embodiment, but not necessarily all embodiments, of the inventions. The phraseology and terminology employed herein is not to be construed as limiting but is for descriptive purpose only. It is to be understood that where the claims or specification refer to “a” or “an” element, such reference is not to be construed as there being only one of that element. It is to be understood that where the specification states that a component feature, structure, or characteristic “may”, “might”, “can” or “could” be included, that particular component, feature, structure, or characteristic is not required to be included.

Reference to terms such as “left”, “right”, “top”, “bottom”, “front” and “back” are intended for use in respect to the orientation of the particular feature, structure, or element within the figures depicting embodiments of the invention. It would be evident that such directional terminology with respect to the actual use of a device has no specific meaning as the device can be employed in a multiplicity of orientations by the user or users.

Reference to terms “including”, “comprising”, “consisting” and grammatical variants thereof do not preclude the addition of one or more components, features, steps, integers or groups thereof and that the terms are not to be construed as specifying components, features, steps or integers. Likewise, the phrase “consisting essentially of”, and grammatical variants thereof, when used herein is not to be construed as excluding additional components, steps, features integers or groups thereof but rather that the additional features, integers, steps, components or groups thereof do not materially alter the basic and novel characteristics of the claimed composition, device or method. If the specification or claims refer to “an additional” element, that does not preclude there being more than one of the additional element.

What is claimed is:

1. A chemical deposition process kit component comprising:
a surface exposed to a deposited thin film when the component is in use in a process chamber;
wherein the surface comprises a plurality of recesses which are substantially semi-spherical in shape.

2. The chemical deposition process kit component of claim 1, wherein
the density of the plurality of recesses is proportional to the amount of the deposited thin film that accumulates on the component when in use.

3. The chemical deposition process kit component of claim 1, wherein
the plurality of recesses are half spherical in shape.

4. A chemical deposition process kit comprising:
a component comprising a surface exposed to a deposited thin film when the component is in use in a process chamber, wherein
the surface comprises a plurality of recesses which are substantially semi-spherical in shape.

5. The chemical deposition process kit component of claim 4, wherein
the plurality of recesses are half spherical in shape.

6. The chemical deposition process kit of claim 4, wherein
the density of the plurality of recesses is proportional to the amount of the deposited thin film that accumulates on the component when in use.

7. A process for modifying a chemical deposition process kit component comprising:
determining a portion of surface of the component that is exposed to a deposited thin film when the component is in use in a process chamber;
determining an amount of the deposited thin film accumulated on the portion of surface; and
forming a plurality of recesses in within the portion of surface, the density of the plurality of recesses being proportional to the amount of the deposited thin film accumulated on the portion of surface.

8. The process of claim 7, wherein
the plurality of recesses are substantially half spherical in shape.

9. The process of claim 7, wherein
the plurality of recesses are substantially semi spherical in shape, a depth of the plurality of recesses being less than half a diameter of the plurality of recesses.

10. The process of claim 7, wherein
the plurality of recesses are formed using a mechanical drilling process.

11. The process of claim 7, wherein
the plurality of recesses are formed using a laser removal process.
